(19) United States
(12) Patent Application Publication
(10) Pub. No.: US 2004/0217005 A1
(43) Pub. Date: Nov. 4, 2004

(54) Method for electroplating bath chemistry control

(76) Inventors: Aron Rosenfeld, Palo Alto, CA (US); Hooman Hafezi, Fremont, CA (US); Zhi-Wen Sun, Palo Alto, CA (US); Michael Yang, Palo Alto, CA (US); Joseph Behnke, Sunnyvale, CA (US)

Correspondence Address: Applied Materials, Patent Counsel - Legal Affairs Department, P.O. Box 450A, Santa Clara, CA, 95052, US

(21) Appl. No.: 10/854,006

(22) Filed: May 25, 2004

Related U.S. Application Data
(63) Continuation-in-part of application No. 10/627,336, filed on Jul. 24, 2003.
Application No. 10/627,336 is a continuation-in-part of application No. 10/268,284, filed on Oct. 9, 2002.
(60) Provisional application No. 60/398,345, filed on Jul. 24, 2002.

(51) Int. Cl. C25D 3/50; C25D 21/12

(52) U.S. Cl. 205/82; 205/84

(57) ABSTRACT

A method for controlling the chemical composition of an electroplating bath solution used to plate a plurality of substrates by providing the electroplating bath solution to a small-volume plating cell configured to minimize additive breakdown, and discarding the electroplating bath after a predetermined bath lifetime. The method includes predetermining a lifetime of an electroplating bath solution having a desired chemical composition, combining a plurality of electroplating bath solution components thereby forming the electroplating bath solution having the desired chemical composition, filling a small-volume plating cell with the electroplating bath solution, plating a plurality of substrates in the electroplating bath solution until the bath lifetime is reached; and discarding the electroplating bath solution after the bath lifetime is reached.

### CROSS-REFERENCE TO RELATED APPLICATIONS

This application is a continuation-in-part of co-pending U.S. patent application Ser. No. 10/627,336, entitled “Electrochemical Processing Cell”, filed Jul. 24, 2003, which is a continuation-in-part of co-pending U.S. patent application Ser. No. 10/268,284, filed Oct. 9, 2002, which claims priority to U.S. Provisional Patent Application Ser. No. 60/398,345, filed Jul. 24, 2002. Each of the aforementioned related patent applications is incorporated by reference herein in its entirety.

### BACKGROUND OF THE INVENTION

1. Field of the Invention

Embodiments of the present invention generally relate to a method for controlling the composition and chemistry of an electroplating bath.

2. Description of the Related Art

Metallization of sub-quarter micron sized features is a foundational technology for present and future generations of integrated circuit manufacturing processes. More particularly, in devices such as ultra large scale integration-type devices, i.e., devices having integrated circuits with more than a million logic gates, the multilevel microelectronic features (e.g., interconnects) that lie at the heart of these devices are generally formed by filling high aspect ratio, i.e., greater than about 3:1, interconnect features with a conductive material, such as copper. Conventionally, electrochemical plating (electroplating) is used to fill interconnect features in ultra large-scale integrated circuit manufacturing processes. Typically during electroplating, a substrate having interconnect features (e.g., trenches, lines, vias) is placed in contact with an electroplating bath solution and an electrical bias is applied between the substrate (cathode) and an anode (e.g., a copper anode) positioned within the plating solution. This bias generates an electrical field which drives positive metal ions (e.g., Cu ions) in the plating solution towards the substrate where the metal ions are reduced and deposited onto the surface of the substrate to fill the interconnect features with copper and plate to a desired thickness.

Although electroplating has become the standard for interconnect metallization, control over the electroplating bath solution chemistry or composition remains a challenge as bath components are consumed and detrimental by-products are generated during normal plating operation. Conventionally, an electroplating bath solution containing electrolyte and various additives is used to plate a large number of substrates, e.g., 1500 or more substrates. Additives are added to the electrolyte to promote bottom-up fill of the features (i.e., gapfill) without voids, to enhance plated film thickness uniformity, and to obtain other desirable plating characteristics in an effort to achieve defect free metallization of high aspect ratio features. For example, a typical electroplating bath contains copper sulfate, acid, chloride ions, and three organic additives. One additive is typically an accelerator which is used for catalyzing the copper reaction at targeted locations on the substrate. A second additive is typically a suppressor which is used to inhibit copper deposition at undesirable locations on the substrate. A third additive is typically a leveler which is used to flatten out the copper growth above convex surfaces, such as surfaces above a trench, line, or via. However, as the additives are consumed during the electrochemical processes and/or degraded, the imbalance in additive concentrations and/or the accumulation of detrimental degradation by-products during normal plating operation lead to voids and plating defects (e.g., plated film thickness nonuniformity, etc.).

Imbalances in additive concentrations during plating are primarily due to consumption during the electrochemical processes and/or additive degradation as a result of electrochemical processes, thermal decomposition, or reactions occurring at the anode surface or cathode surface. Additive concentrations in the electroplating bath solution are also affected by evaporation of water from the electrolyte, inclusion of additives in the films deposited, and drag-out of additives with the removal of the plated substrates from the electroplating bath solution. In another aspect, the generation of additive degradation by-products leads to a random or uncharacterized deposition process. When additives break down, the resulting by-products may effectively be incorporated into the plated film as dopants. Although some by-products incorporated into the plated film may have desirable effects, such as enhancing the electromigration resistance of the plated film (e.g., copper interconnect), there are some detrimental degradation by-products that lead to voids and plating defects.

On-line monitoring and a bleed-and-feed methodology is conventionally employed to maintain the bath chemistry within an acceptable operating window. An analyzer module and a dosing module are integrated on-line or in-line to monitor and maintain the desired concentrations of the various additives in the main electrolyte supply tank. A sample line provides electrolyte from the main tank (bleed) to the analyzer for determination of the additive concentrations at prescribed time intervals which, in turn, is used to control the dosing module for delivery of fresh additives and electrolyte (feed) to the main tank. In conjunction with this delivery of fresh additives and electrolyte, a prescribed amount of aged electrolyte is generally sent to drain from the main tank so as to maintain the concentration of organic breakdown by-products at acceptable levels as well as to maintain the overall volume of electrolyte. This bleed-and-feed methodology is employed to maintain the bath chemistry within an acceptable operating window and typically replenishes about 10 vol. % to about 20 vol. %, for example, of a 200 liter electrolyte tank per day.

A limitation of the bleed-and-feed approach is that there are a very limited number of analytical techniques that may be implemented by the analyzer module for accurately monitoring plating bath additives with the throughput necessary to provide useful bath concentration measurements within an acceptable lag time due to the bath composition changing over time. A technique that has become most widely adopted is cyclic voltammetric stripping (CVS), wherein the potential of an inert electrode in a sample test cell is cycled over a specified voltage range such that a small amount of metal, such as copper (Cu), is alternately plated and stripped (i.e., removed) from the electrode. The measured charge and integrated current of the stripping peak region is known to be proportional to the plating rate which, in turn, is strongly dependent on the additive concentration of the plating additives. Therefore, with calibration, the plating rate can be quantitatively correlated with the additive concentration. However, with an increasing number of additives, this technique may become too slow for the throughput desired. CVS systems are commercially available, for example, from Applied Materials, Santa Clara, Calif. and from ECI Technology, East Rutherford, N.J. Other techniques such as Gel Permeation Chromatography are able to accurately quantify additive concentrations but in practice suffer from being too slow for on-line analysis.

On-line monitoring and bleed-and-feed approaches to maintaining additive concentrations have effectively constrained the development of new additive formulations for improving deposition, as these approaches limit the additives that may be used to those additives that are amenable to measurement by conventional analytical techniques. These approaches also limit combinations of additives that may be used to those in which the individual additives are separately quantifiable when used together. Additionally, a practical limitation to these approaches is the number of additives that can be used in combination when the time for individual, sequential analysis of additives exceeds the throughput necessary for providing real-time bath concentration data.

In particular, the use of CVS inherently restricts the use of additives for improving deposition to only certain additives amenable to measurement. Additives not directed to affecting the plating rate are not amenable to CVS measurement. Such additives include certain anti-foaming additives for the prevention of voids and defects due to bubble formation and additives for enhancing wettability. The anti-foaming additives not amenable to CVS measurement include, for example, octyl alcohol, lauryl alcohol, and other moderate to high molecular weight alcohols. Additional information on anti-foaming agents for reducing voids and plating defects can be found in the commonly assigned U.S. patent application Ser. No. 10/410,105, filed on Apr. 9, 2003, which is incorporated by reference herein to the extent not inconsistent with the claimed aspects and description herein.

In addition, different suppressor molecules that have similar CVS activity but are formulated to impart additional desirable properties, such as enhanced wettability, are not independently measurable when used together, and therefore, the relative amounts of such additives used in combination can not be controlled. For example, polyether compounds are conventionally used as suppressors. Preferable suppressors include polypropylene propanols and polypropylene glycols which contain the group (C₃H₆O)ₘ, where m is an integer ranging in value from about 6 to about 20. Also preferred are similar polyethylene compounds which contain the group (C₂H₄O)ₙ where n is an integer greater than about 6. When added to a bath, these compounds are typically added as a polyethylene oxide/polypropylene oxide (EO/PO) random or block copolymer. Varying the relative proportion of EO chains to PO chains, and/or modifying the termination of the polymer chain imparts different properties such as wettability. Generally, the overall suppressor power and wetting properties of the copolymer will vary with the particular EO/PO configuration and termination of the polymer chain. However, it is difficult to optimize both the suppressor and wetting properties with a single EO/PO copolymer, and the introduction of a second EO/PO copolymer to optimize these properties is not conventionally employed where the properties and molecular structure of the two EO/PO copolymers are not dissimilar enough for the CVS activity of each EO/PO copolymer to be independently measurable. Additional information on the wide range of wetting behavior of EO/PO copolymers can be found in U.S. Pat. No. 5,071,591, filed on Oct. 26, 1990.

Therefore, a need exists for an improved method for controlling electroplating bath chemistry and repeatability for any additive and electroplating bath chemistry, while minimizing waste.

### SUMMARY OF THE INVENTION

The present invention generally provides a method for controlling the chemical composition of an electroplating bath, including the sequential steps of predetermining a lifetime of an electroplating bath solution having a desired chemical composition, filling a small-volume plating cell with the electroplating bath solution, plating a plurality of substrates in the electroplating bath solution until the lifetime is reached, and discarding the electroplating bath solution after the predetermined bath lifetime.

In a preferred embodiment, a method for controlling electroplating bath chemistry, including the sequential steps of predetermining a lifetime of an electroplating bath solution having a desired chemical composition, filling a small-volume plating cell with the electroplating bath solution wherein the plating cell is configured to minimize additive breakdown, plating a plurality of substrates in the electroplating bath solution until the lifetime is reached, and discarding the electroplating bath solution after the predetermined bath lifetime.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a top plan view of one embodiment of an electrochemical plating system of the invention.

FIG. 2 illustrates a partial sectional perspective view of an exemplary electrochemical plating cell.

### DETAILED DESCRIPTION OF THE PREFERRED EMBODIMENT

The present invention generally provides a method for controlling the chemical composition of an electroplating bath solution used to deposit a metal on a surface of a substrate by providing a small-volume of electroplating bath configured to minimize additive breakdown, and discarding the electroplating bath after a predetermined bath lifetime. The present invention generally employs a small volume electrochemical plating cell, i.e., a cell that houses a volume of electrolyte in a range of between about 1 liter and 25 liters, preferably between about 10 and 20 liters, supplied by an adjacent fluidly connected tank. The electroplating bath solution (plating fluid) is used to plate metal onto a number of substrates, e.g., 100 substrates or more, for a predetermined lifetime of the plating fluid, after which the plating fluid is discarded and replaced with new plating fluid. These small volumes of plating fluid are utilized to minimize waste. Control of the electroplating bath chemistry is achieved, without the need for monitoring the bath solution chemistry, by plating with the small-volume of plating fluid only for the duration of the predetermined lifetime of the plating fluid. After the lifetime of the plating fluid is reached, the volume of plating fluid drained is at least about 60 vol. %, and preferably between about 80 vol. % and about 100 vol. %.

In another embodiment, a method for controlling electroplating bath chemistry, includes the sequential steps of predetermining a lifetime of an electroplating bath solution having a desired chemical composition (e.g., including additives), filling a small-volume plating cell with the electroplating bath solution wherein the plating cell is configured to minimize additive breakdown, plating a plurality of substrates in the electroplating bath solution until the lifetime is reached, and discarding the electroplating bath solution after the predetermined bath lifetime. Here the small-volume plating cell is configured to fluidly separate the catholyte (i.e., electroplating bath solution containing additives) from the anode to minimize additive breakdown at the anode surface. This configuration of fluidly separating the catholyte from the anode extends the lifetime of the electroplating bath solution (i.e., catholyte) and consequently minimizes waste. Each small volume of plating fluid may be used to plate a number of substrates in the range of about 150 to about 500 substrates, depending upon the particular electroplating bath solution composition (recipe), substrate size, and other desired plating characteristics (e.g., plating thickness, feature design, etc.).

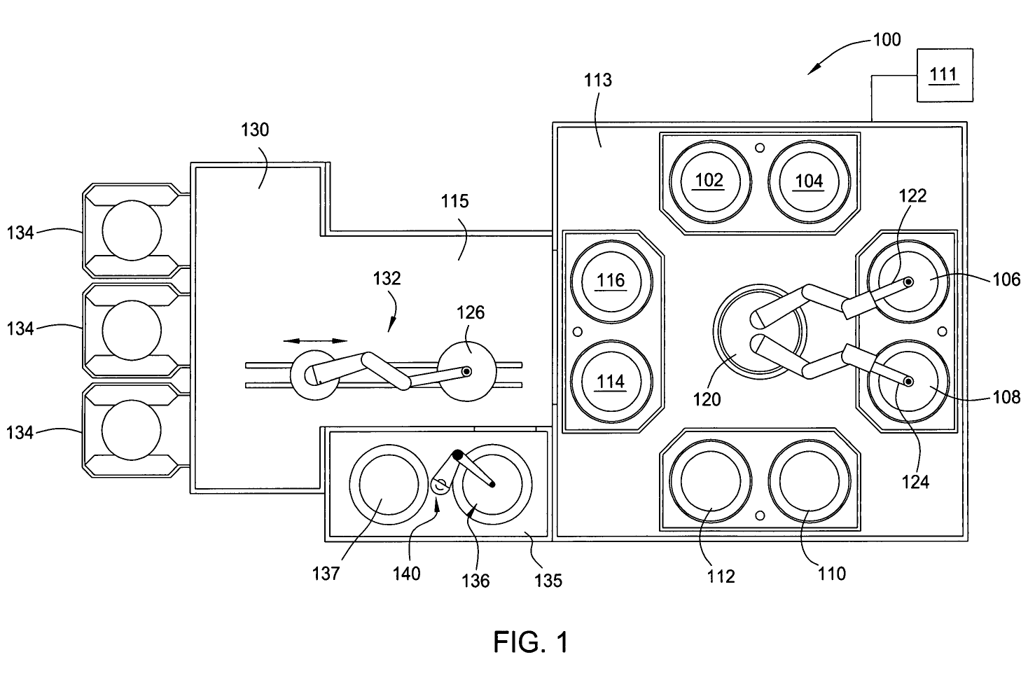

The processes described herein are performed in an apparatus suitable for performing electroplating deposition onto semiconductor substrates or into high aspect ratio features. Electroplating substrate processing platforms generally include an integrated processing platform having one or more substrate transfer robots, and one or more processing cells or chambers for cleaning (e.g., spin-rinse-dry or bevel clean), annealing, and electroplating a conductive material onto a substrate. FIG. 1 illustrates a top plan view of an exemplary electrochemical plating (ECP) system 100. ECP system 100 has a factory interface (FI) 130, also termed a substrate loading station, configured to interface with substrate containing cassettes 134. A robot 132 is configured to access substrates contained in the cassettes 134 and traverse into a link tunnel 115, which connects FI 130 to a processing mainframe 113, to deliver one or more substrates 126 to one of the processing cells 114, 116, or to the annealing station 135. A robot 140 is generally configured to move substrates between the respective heating 137 and cooling plates 136 of the annealing station 135.

Processing mainframe 113 has a substrate transfer robot 120 having one or more arms/blades 122, 124 configured to support and transfer substrates to and from a plurality of processing locations 102, 104, 106, 108, 110, 112, 114, 116. Process locations 102, 104, 106, 108, 110, 112, 114, 116 may be any number of processing cells utilized in an electrochemical plating platform, such as electrochemical plating cells, rinsing cells, bevel clean cells, spin rinse dry cells, substrate surface cleaning cells, electroless plating cells, metrology inspection stations, and/or other processing cells that may be beneficially used in conjunction with a plating platform.

Robot 132 may also be used to retrieve substrates from the processing cells 114, 116 or the annealing chamber 135, after a substrate processing sequence is complete, and deliver the substrate back to one of the cassettes 134 for removal from system 100. Each of the respective processing cells and robots are generally in communication with a process controller 111 configured to receive inputs from both a user and/or various sensors positioned on the system 100 and control the operation of system 100 in accordance with the inputs. Additional configurations and implementations of an electrochemical processing system are illustrated in commonly assigned U.S. patent application Ser. No. 10/616,284, filed on Jul. 8, 2003, entitled “Multi-Chemistry Plating System”, which is incorporated herein by reference in its entirety.

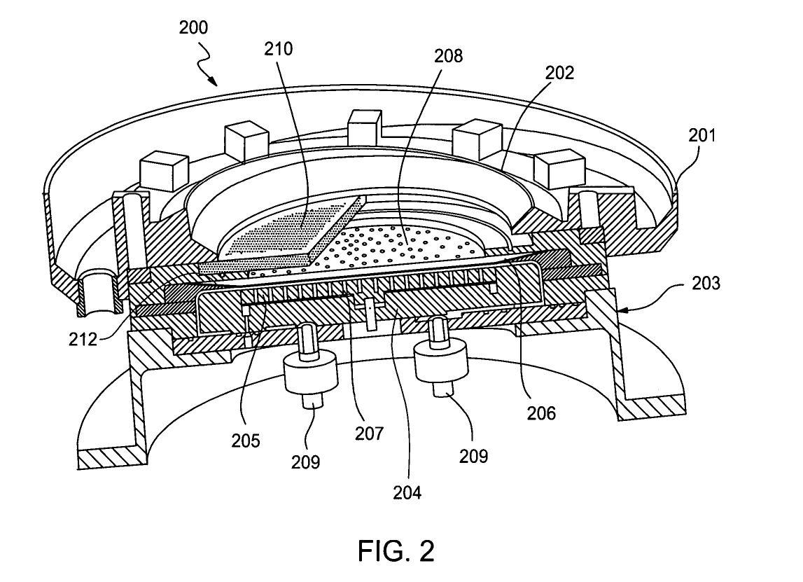

FIG. 2 illustrates a partial perspective and sectional view of an exemplary electrochemical plating cell 200 that may be implemented in processing locations 102, 104, 110, and 112. The electrochemical plating cell 200 includes an outer basin 201 and an inner basin 202 positioned within outer basin 201. Inner basin 202 is configured to contain a plating solution that is used to plate a metal, e.g., copper, onto a substrate during an electrochemical plating process. During the plating process, the plating solution is generally continuously supplied to inner basin 202 such that the plating solution continually overflows the uppermost point (generally termed a “weir”) of inner basin 202 and is collected by outer basin 201 and drained therefrom for recirculation during the lifetime of the plating fluid. Upon reaching the predetermined lifetime of the plating fluid, the plating fluid is drained and discarded.

For enhanced plating, plating cell 200 is generally positioned at a tilt angle and the uppermost portion of inner basin 202 may be extended upward on one side of plating cell 200, such that the uppermost point of inner basin 202 is generally horizontal and allows for contiguous overflow of the plating solution supplied thereto around the perimeter of inner basin 202. Base member 204 is positioned in a support ring 203 and includes an annular or disk shaped recess configured to receive an anode member 205, a plurality conduits (not shown), and fluid inlets/drains 209 extending from a lower surface thereof. Each of the fluid inlets/drains 209 are generally configured to individually supply or drain a fluid to or from either the anode compartment (anolyte) or the cathode compartment (catholyte) of plating cell 200.

Anode member 205, typically a copper anode, includes a plurality of slots 207 formed therethrough, wherein the slots 207 are configured to remove a dense fluid layer (sludge) from the anode surface during plating processes. The current path from the lower side of anode to the upper side of anode generally includes a back and forth type path between the slots 207.

A membrane support assembly 206 is generally secured at an outer periphery thereof to base member 204 and has an interior region 208 configured to allow fluids to pass therethrough. A membrane 212 stretched across a lower surface of the membrane support assembly 206 operates to fluidly separate a catholyte chamber portion and an anolyte chamber portion of the plating cell. A diffusion plate 210, positioned within the catholyte chamber portion, is generally a porous ceramic disk member configured to generate an evenly distributed and substantially laminar flow of plating fluid in the direction of the substrate being plated. The exemplary plating cell is further described in commonly assigned U.S. patent application Ser. No. 10/268,284, filed on Oct. 9, 2002, entitled “Electrochemical Processing Cell”, which claims priority to U.S. Provisional Application Ser. No. 60/398,345, filed on Jul. 24, 2002, both of which are incorporated herein by reference in their entireties.

The membrane 212 generally operates to fluidly isolate the anode chamber from the cathode chamber of the plating cell. Membrane 212 is generally an ionic membrane having fixed negatively charged groups, such as SO₃⁻, COO⁻, HPO₂⁻, SeO₃⁻, PO₃²⁻, or other negatively charged groups amenable to plating processes which allows only certain types of ions to travel through the membrane. For example, membrane 212 may be a cationic membrane that is configured to facilitate positively charged copper ions (Cu²⁺) to pass therethrough, i.e., to allow copper ions to travel from the anode in the anolyte solution through the membrane 212 into the catholyte solution, where the copper ions may then be plated onto the substrate. Concurrently, the cationic membrane having negatively charged ion groups (e.g., SO₃⁻) prevents the passage of negatively charged ions and electrically neutral species of the plating solution (e.g., catholyte additives) in the cathode chamber from traveling into the anode chamber. It is desirable to prevent these catholyte additives (e.g., accelerators) from traveling through the membrane 212 and contacting the anode, as the additives are known to break down upon contacting the anode. Examples of suitable membranes include a Nafion®-type membrane having a poly (tetrafluoroethylene) based ionomer manufactured by Dupont Corporation, and other cationic and anionic membranes such as CMX-SB ionic membranes manufactured by Tokuyama of Japan, Ionics CR-type membranes from Ionics Inc., Vicor membranes, Neosepta® membranes manufactured by Tokuyama, Aciplex® membranes, Selemlon® membranes, Flemion membranes from Asahi Corporation, Raipare™ membranes from Pall Gellman Sciences Corporation, and C-class membranes from Solvay Corporation. The membranes described herein are more fully described in the commonly assigned U.S. patent application Ser. No. 10/616,044, filed Jul. 8, 2003, which is incorporated herein by reference in its entirety.

In operation, the electrochemical plating cell is generally configured to fluidly isolate an anode of the plating cell from a cathode or plating electrode of the plating cell via an ionic membrane positioned between the substrate being plated and the anode of the plating cell. Additionally, the plating cell is generally configured to provide a first fluid solution (anolyte) to an anode compartment, i.e., the volume between the upper surface of the anode and the lower surface of the membrane, and a second fluid solution (plating solution; catholyte) to the cathode compartment, i.e., the volume above the upper membrane surface.

A substrate is first immersed into a catholyte contained within inner basin 202. Once the substrate is immersed in the catholyte, which generally contains copper sulfate, chlorine, and a plurality of organic plating additives (levelers, suppressors, accelerators, etc.) formulated to enhance plating, an electrical plating bias is applied between the substrate, which effectively acts as a cathode, and the anode 205 positioned in a lower portion of plating cell 200. The electrical plating bias generally operates to cause metal ions in the catholyte to deposit on the cathodic substrate surface. The catholyte supplied to inner basin 202 is continually circulated through inner basin 202 via fluid inlet/outlets 209. More particularly, the catholyte may be introduced to plating cell 200 via a fluid inlet 209. The catholyte may be routed across the lower surface of base member 204 and upward through internal apertures or conduits. The catholyte may then be introduced into the cathode chamber via a channel formed into plating cell 200 that communicates with the cathode chamber at a point above membrane support 206. Similarly, catholyte may be removed from the cathode chamber via a fluid drain positioned above membrane support 206, where the fluid drain is in fluid communication with one of fluid drains 209 positioned on the lower surface of base member 204. Likewise, anolyte may be separately introduced and drained from the anolyte compartment via the fluid inlet/outlets 209 and internal conduits of base member 204.

Once the catholyte is introduced into the cathode chamber, the plating solution travels upward through diffusion plate 210. Diffusion plate 210, which is generally a ceramic or other porous disk shaped member, generally evens out the flow pattern across the surface of the substrate and also operates to resistively dampen electrical variations in the electrochemically active area of the anode and/or ionic membrane surface, which otherwise is known to produce plating nonuniformities. However, the catholyte introduced into the cathode chamber, which is generally a plating solution containing additives, is not permitted to travel downward through the membrane 212 positioned on a lower surface of membrane support assembly 206 into the anode chamber, as the anode chamber is fluidly isolated from the cathode chamber by the membrane 212. The anode chamber includes separate individual fluid supply and drain sources configured to supply an anolyte solution to the anode chamber. The solution supplied to the anode chamber, which may generally be copper sulfate in a copper electrochemical plating system, circulates exclusively through the anode chamber and does not diffuse or otherwise travel into the cathode chamber, as the membrane 212 positioned on membrane support assembly 206 is not fluid permeable in either direction.

Additionally, the flow of the anolyte, i.e., an electroplating bath solution without additives, into the anode chamber is directionally controlled in order to maximize plating parameters. For example, anolyte may be communicated to the anode chamber via an individual fluid inlet 209. Fluid inlet 209 is in fluid communication with a fluid channel formed into a lower portion of base member 204 and apertures of base member 204 which communicate with the interior of anolyte chamber. Thereafter, the anolyte travels across the upper surface of the anode 205 below the membrane positioned immediately above, towards the opposing side of base member 204. Once the anolyte reaches the opposing side of anode 205, it is received into a corresponding fluid channel and drained from plating cell 200 for recirculation. The processing platforms and electroplating processing cells described herein are more fully described in the commonly assigned U.S. patent application Ser. No. 10/268,284, filed Oct. 9, 2002, and commonly assigned U.S. patent application Ser. No. 10/627,336, filed on Jul. 24, 2003, both of which are incorporated by reference herein in their entireties.

The catholyte provided to the electrochemical plating cell is generally a plating solution containing additives. The catholyte solution is generally formed by combining several fluid components prior to use. For example, one fluid component may be an aqueous plating solution without additives, such as Ultrafill™ or other electrolytes commercially available from Shipley Ronal of Marlborough, Mass. or electrolytes, such as Viaform™, commercially available from Enthone, a division of Cookson Electronics PWB Materials & Chemistry of London. The aqueous plating solution is typically a low acid-type plating solution having between about 5 g/l of acid and about 50 g/l of acid, and preferably between about 5 g/l and about 10 g/l of acid. The acid may be sulfuric acid, sulfonic acid (including alkane sulfonic acids), as well as other acids known to support electrochemical plating processes. The desired copper concentration in the catholyte is generally between about 25 g/l and about 70 g/l, preferably between about 30 g/l and about 50 g/l of copper. The copper is generally provided to the solution via copper sulfate, and/or through the electrolytic reaction of the plating process wherein copper ions are provided to the solution via the anolyte from a soluble copper anode source. More particularly, copper sulfate pentahydrate (CuSO₄•5H₂O) may be diluted to obtain a copper concentration of about 40 g/l, for example. A common acid and copper source combination is sulfuric acid and copper sulfate, for example. The catholyte also has chlorine ions, which may be supplied by hydrochloric acid or copper chloride, for example, and the concentration of the chlorine may be between about 30 ppm and about 60 ppm. In addition to conventional acids, or as a substitute to conventional acids, alternative plating solutions may be used containing pyrophosphoric acid or ethylenediamine, with additions of malonic acid, citric acid, and/or tartaric acid.

The catholyte also has one or more additives, provided by one or more fluid components combined in forming the catholyte, that promote desirable plating characteristics such as bottom up via/trench fill, fill rate, uniformity, etc. The additives include levelers, suppressors, and accelerators. Suppressors are typically added to the solution in a concentration of between about 1.5 ml/l and about 4 ml/l, and preferably between about 2 ml/l and 3.0 ml/l. Exemplary suppressors include ethylene oxide and propylene oxide copolymers. Accelerators are added to the solution in a concentration of between about 3 ml/l and about 10 ml/l, preferably within the range of between about 4.5 ml/l and 8.5 ml/l. Exemplary accelerators include sulfopropyl-disulfide, mercapto-propane-sulphonate, and their derivatives. Levelers are added to the solution at a concentration of between about 1 ml/l and about 12 ml/l, or more particularly, in the range of between about 1.5 ml/l and 4 ml/l.

The present invention utilizes a dosing unit to accurately provide the desired amounts of a plurality of electroplating bath solution components for formulating an electroplating bath solution (catholyte) having a desired chemical composition. The dosing unit generally comprises fluid metering devices to precisely measure the desired amount of one or more components. In a preferred embodiment, at least one fluid metering device employs volumetric metering for accurately measuring a desired volume (dose) of one or more components. Furthermore, analysis to validate dosing accuracy may be advantageously conducted on the individual components at the dosing unit or prior to combining the components of the catholyte. An advantage of validating dosing accuracy at the component level (i.e., prior to combining the individual components), is that conventional analysis techniques (e.g., CVS) not amenable to distinguishing certain mixtures of additives, may be used to validate dosing accuracy of an individual component or additive. After the correct proportions of the components have been measured, the components are combined to provide a catholyte having the desired chemistry. Examples of a plating solution delivery system and a dosing pump (fluid metering device) are more fully described in commonly assigned U.S. patent application Ser. No. 10/616,284, filed Jul. 8, 2003, which is incorporated herein by reference in its entirety.

The present invention advantageously permits the use of essentially any additive formulation and extends the flexibility in formulating and developing additives to meet the increasing challenges of feature filling. For example, the present approach enables the use of inorganic and organic additives not previously amenable to on-line monitoring (e.g., CVS). Additives that improve plating and may be advantageously used with the present invention include accelerators such as mercapto-propyl-sulfonic acid (MPS) HS—CH₂—CH₂—CH₂—SO₃H, thioreas, and derivatives thereof. Levelers that may be advantageously used with the present invention include sulfur-containing and/or nitrogen-based levelers. Wetting agents, anti-foaming agents, anti-oxidants, and/or detergents may also be advantageously used with the present invention. For example, anti-foaming agents previously not amenable to measurement and monitoring, for the prevention of bubble formation and/or enhancing wettability, that may be advantageously used include octyl alcohol, lauryl alcohol, and other moderate to high molecular weight alcohols such as C6 to C20 alcohols, monohydric alcohols, polyhydric alcohols, and any mixtures and derivatives thereof. Additional information on anti-foaming agents for reducing plating defects can be found in the commonly assigned U.S. patent application Ser. No. 10/410,105, filed Apr. 9, 2003. In another example, the use of chemically similar additives not previously amenable to on-line CVS metrology may be advantageously used together to enhance plating. For example, the present approach enables the use of two or more chemically similar EO/PO copolymers to allow optimizing both suppressor and wetting properties to improve plating characteristics.

In another aspect, the present invention advantageously permits the use of dopant additives that may be controllably and reproducibly incorporated into the plated film. In particular, the dopant additive may be a molecule tailored to be similar to a by-product of a conventional additive known to produce desirable effects in the plated film. For example, a dopant additive may be a carbon-containing dopant that incorporates carbon into the plated film for enhancing the electromigration resistance of the plated film. Suitable carbon-containing dopants include isopropyl alcohol, ethylene glycol, tetraethylene glycol, polyethylene glycol, and polypropylene glycol. These carbon-containing dopants, hereafter referred to as electromigration resistive additives, have an average molecular weight in a range of about 100 to about 1000, preferably about 200 to about 600. These low molecular weights below about 1000 have diminished suppressive effectiveness and molecular weights less than about 600 are not detectable by CVS. This approach of introducing dopant additives eliminates the need for tailoring electroplating bath recipes to break down the conventional organic additives to beneficial breakdown by-products which also results in the introduction of detrimental degradation by-products and a random and non-reproducible or uncharacterized process. This approach of introducing dopant additives into the electroplating bath also eliminates the need of an extra post-processing step as a means of introducing a beneficial dopant additive such as by ion implantation.

In another aspect, the present invention advantageously permits the use of inorganic and organic additives in addition to conventional additives, for example, as the fourth or fifth additive components, and/or used in lieu of certain conventional additives. Another important advantage of the present invention is this method enables the use of essentially any number of additives. Eliminating the requirement of on-line monitoring, the present approach provides the flexibility of incorporating any number of additives in the electroplating bath solution or catholyte for improving the plating process.

The anolyte provided to the electrochemical plating cell is generally a plating solution without additives (e.g, electrolyte). The anolyte solution, contained in the volume below the membrane and above the anode may be simply the catholyte solution without the plating additives. However, the inventors have found that specific anolyte solutions, other than just stripped catholyte solutions, enhance copper transfer through the membrane and prevent copper sulfate and hydroxide precipitation which passivates the surface of the anode. When the pH of the anolyte is maintained above about 4.5 to about 4.8, copper hydroxide starts to deposit from Cu salt solutions, i.e., Cu²⁺+2H₂O=Cu(OH)₂ (deposit)+2H⁺. If the anolyte is configured to supply between about 90% and about 100% of the copper to the catholyte, the membrane effectively operates as a clean copper anode, i.e., the membrane provides copper to the catholyte without the disadvantages associated with the electrochemical reaction that takes place at the surface of the anode (sludge formation, additive consumption, planarity variations due to erosion, etc.). The anolyte of the invention generally includes a soluble copper II salt, such as copper sulfate, copper sulfonate, copper chloride, copper bromide, copper nitrate, or a combination thereof, in an amount sufficient to provide a concentration of copper ions in the catholyte of between about 0.1 M and about 2.5 M, or more particularly, between about 0.25 M and about 2 M.

The lifetime of an electroplating bath solution (i.e., catholyte), is determined by one or more auxiliary experiments. A lifetime for a particular catholyte composition and catholyte volume may be characterized as a number of wafers that can be plated prior to causing an unacceptable amount of voids or plating defects for a particular substrate design, substrate size, and/or other desired plating characteristics (e.g., plating thickness). Alternatively, a lifetime may be characterized in terms of one or more relevant processing parameters, such as, an amount of additive degradation, a number of usable amp-hrs of current or current density the particular catholyte may undergo prior to causing an unacceptable amount of voids or plating defects. In another alternative, a lifetime may be characterized as an amount of elapsed time (plating and idle time) after combining a plurality of component fluids to formulate the electroplating bath solution prior to causing an unacceptable amount of voids or plating defects. In practice, because the lifetime of a catholyte is a function of the number of plated substrates, amp-hrs of current passed and elapsed time, a lifetime is preferably a value based on a combination (e.g., an arithmetic combination) of these lifetimes, or alternatively may be determined empirically for the particular catholyte composition and a given set of processing parameters, so as to maintain the desired plating characteristics until the lifetime is reached.

Plating performance may be evaluated in terms of gapfill (e.g., complete feature fill without voids) and various plating characteristics such as plated film morphology, thickness uniformity, surface roughness, desired grain structure, conductivity performance, electromigration and stress migration performance. Unacceptable deviation from any of the desired plating characteristics is referred to as a plating defect. In order to achieve the desired gapfill and plating characteristics, the electroplating bath components must be maintained within specified operating ranges. These ranges may be different for the individual bath components. Typically at least one component concentration may have a narrower operating range than the other components of the electroplating bath. For example, the concentration window of the accelerator additive component required to ensure the specified gapfill performance may be narrower than the concentration window for the electromigration resistive additive component required to ensure adequate electromigration performance. As such, the accelerator would be considered the limiting bath component or most sensitive/critical bath component of the bath for ensuring the desired plating characteristics are achieved.

Determination of the lifetime of an electroplating bath solution (i.e., catholyte) may be made empirically or by a wide variety of methodologies. One methodology to determine the lifetime of an electroplating bath solution is by first determining the depletion rate and/or the by-product build-up rate of detrimental by-products generated for each component of a particular electroplating bath solution composition (i.e., initial composition or plating recipe) for a given substrate size, substrate feature dimensions, plating thickness, and processing parameters (e.g., current density, deplating current, plating time, idle time, etc.) to be used in production. By monitoring the plating characteristics of the plated substrates, an allowable electroplating bath chemistry window for the key bath component(s) may be determined in order to ensure the desired plating characteristics are achieved.

After determining the allowable electroplating bath chemistry window for the key bath component(s), identification of the most sensitive/critical bath component(s) in terms of rate of depletion or generation of detrimental by-products and the corresponding sensitivity of the desired plating characteristics may be identified. The most critical bath component is typically the component that depletes the fastest and/or the most sensitive component in terms of required plating characteristic. For example, typically the accelerator additive both depletes the fastest and is also the most sensitive for the most critical plating parameter gapfill. However, identification of the most critical bath component(s) will vary depending upon the particular electroplating bath solution recipe, desired processing parameters, substrate feature dimensions, and required plating characteristics.

The combination of the known allowable electroplating bath chemistry operating window for the key bath component(s) required to ensure that the desired plating characteristics are achieved and of the known rate of depletion and/or the by-product build-up rate of detrimental by-products generated for each component of the particular electroplating bath solution recipe for the processing parameters to be used in production, will define the useful life of each of the key bath component(s) in terms of number of substrates plated, amp-hrs of current passed, elapsed time, and/or a combination thereof. The shortest useful life, corresponding to one key bath component, becomes the lifetime of the particular electroplating bath solution recipe after which time the bath is discarded.

Lifetime data for one or more electroplating bath solution recipes may be collected in a database for future use during production and/or represented by a suitable algorithm. An algorithm maybe be developed to execute a mathematically based operation using one or more input parameters, wherein the one or more input parameters include substrate size, substrate feature dimensions, a desired plating thickness, a number of amp-hrs of current passed through the electroplating bath solution, a current density, a number of substrates plated, an amount of elapsed plating time, and an amount of elapsed idle time, or other production processing parameters.

### EXAMPLE

To determine the lifetime of a particular electroplating bath solution, a first auxiliary experiment was performed on 500 wafers having a wafer size of 300 mm, wafer feature dimensions of 0.16 μm×0.8 μm and aspect ratio of 5:1, using a production current ramp of 5/500 (i.e., 5 mA/cm² per 500 Å), 10/1000, 40/6500 resulting in a total plating thickness of 8000 Å. During plating, bath samples were withdrawn from the bath at an interval of about 50 plated wafers. The accelerator additive, namely sulfopropyl disulfide (SPS), was found to be the fastest depleting component in the bath having an initial concentration of about 7.5 ml/l (initial dose) and monotonically decreasing to a concentration of below about 5 ml/l after plating 500 wafers. In comparison, the leveler showed a smaller rate of depletion and the suppressor showed minimal depletion. As the accelerator concentration decreased, the concentration of a breakdown by-product of the accelerator, namely propane disulphonic acid (PDS), monotonically increased. Similarly, the breakdown by-products of the leveler and the suppressor were measured for each bath sample. Measurements of the bath component concentrations for each bath sample were made using a mass spectrometer. Alternatively, the concentrations can be determined using CVS analysis.

In a second auxiliary experiment, an allowable electroplating bath chemistry window for the accelerator, leveler and suppressor additives (i.e., the key bath component(s)) was determined in terms of gapfill performance. A large number of electroplating baths were prepared having a range of additive concentration combinations. Accelerator additive concentrations were in a range from about 5 ml/l to about 8 ml/l, leveler additive concentrations were in a range from about 1.5 ml/l to about 4 ml/l, and the suppressor additive concentrations were in a range from about about 1.5 ml/l to about 3 ml/l. Wafer samples having wafer feature dimensions of 0.16 μm×0.8 μm and an aspect ratio of 5:1, were plated in each of the baths. Gapfill performance was evaluated by cross-sectioning the plated wafer features and examining the gapfill for voids using a focused ion beam (FIB) scanning microscope. From this analysis, it was found that good gapfill was achieved over the accelerator concentration range of about 6 ml/l to about 8 ml/l with relatively little sensitivity on the concentrations of the leveler and suppressor additive concentrations except at their highest and lowest concentration values (1.5 ml/l, 3 ml/l, and 4 ml/l).

Similar auxiliary experiments were performed for determining an allowable electroplating bath chemistry window for the accelerator, leveler and suppressor additives in terms of plated film morphology, thickness uniformity, and surface roughness. It was found that the electroplating bath chemistry window determined in terms of gapfill gave the tightest operating window in that gapfill was the most sensitive plating characteristic as a function of the three additive components. Of the three additives, the accelerator additive displayed the shortest useful life because of it was found to deplete the fastest. Thus, the useful life of the accelerator is determinative of the lifetime of a particular electroplating plating bath solution. From the known allowable electroplating bath chemistry operating window of about 6 ml/l to about 8 ml/l for the accelerator and the known rate of depletion of the accelerator concentration for the processing parameters to be used in production, as measured in the first auxiliary experiment, the minimum allowable accelerator concentration of 6 ml/l occurred after 250 wafers were plated. As such, the lifetime of the particular electroplating bath solution is 250 wafers, after which time the bath is discarded.

To validate the determined lifetime of 250 wafers for the electroplating bath solution, three plating cells were concurrently filled with the electroplating bath solution, patterned 300 mm wafers were plated in each cell until a wafer count of 250 was reached, and then the bath in each cell was discarded. This cycle was repeated three times for a production of 1000 plated wafers using four baths in each cell for a total of 3000 wafers. Bath samples were taken from each cell at about the beginning, middle and end of the lifetime of each bath and the concentration of the accelerator, suppressor and leveler additives were measured by CVS. Over the lifetime of each of the baths, the accelerator additive concentration was found to monotonically decrease from an initial dosing concentration of about 7.5 ml/l to a minimum concentration of about 6 ml/l after plating the 250^{th} wafer in accordance with the prescribed operating window from the auxiliary experiments. In comparison, the suppressor and lever concentrations remained relatively constant up to around wafer number 250. Gapfill performance was evaluated for wafers plated at around the beginning and the end of the third bath lifetime for each of the three cells. Using FIB, it was observed that perfect gapfill is achieved over the entire lifetime of the bath.

While the foregoing is directed to embodiments of the present invention, other and further embodiments of the invention may be devised without departing from the basic scope thereof, and the scope thereof is determined by the claims that follow.

1. A method for controlling electroplating bath chemistry, comprising:
(a) determining a lifetime of an electroplating bath solution having a desired chemical composition including one or more additives;
(b) filling a small-volume plating cell with the electroplating bath solution;
(c) plating a plurality of substrates in the electroplating bath solution until the lifetime is reached; and then
(d) discarding the electroplating bath solution after the lifetime is reached.

2. The method of claim 1, further comprising repeating (b), (c), and then (d).

3. The method of claim 1, wherein the determining a lifetime of an electroplating bath solution having a desired chemical composition comprises identifying the onset of voids or plating defects.

4. The method of claim 1, wherein the determining a lifetime of an electroplating bath solution comprises conducting one or more auxiliary experiments to identify a depletion rate of one or more critical bath components or a rate of generation of one or more detrimental by-products.

5. The method of claim 1, wherein the lifetime comprises a value selected from a group consisting of a number of amp-hrs of current passed through the electroplating bath solution, a number of substrates plated, an amount of elapsed time after combining a plurality of component fluids to formulate the electroplating bath solution, or a combination thereof.

6. The method of claim 1, wherein the lifetime comprises a value generated from an algorithm, wherein the algorithm executes a mathematically based operation using one or more input parameters, wherein the one or more input parameters is selected from a group consisting of a substrate size, a desired plating thickness, a number of amp-hrs of current passed through the electroplating bath solution, a current density, a number of substrates plated, an amount of elapsed plating time, and an amount of elapsed idle time.

7. The method of claim 1, wherein the filling a small-volume plating cell further comprises the steps of volumetrically metering a plurality of component fluids and then mixing the plurality of component fluids to formulate the electroplating bath solution just prior to filling the small-volume plating cell with the electroplating bath solution.

8. The method of claim 1, wherein the filling a small-volume plating cell further comprises recirculating the electroplating bath solution to the cell.

9. The method of claim 1, wherein the electroplating bath solution comprises at least one anti-foaming additive component selected from the group consisting of octyl alcohol, lauryl alcohol, C6 to C20 alcohols, monohydric alcohols, polyhydric alcohols, derivatives thereof, and combinations thereof.

10. The method of claim 1, wherein the electroplating bath solution comprises at least one electromigration resistive additive component selected from the group consisting of isopropyl alcohol, ethylene glycol, tetraethylene glycol, polyethylene glycol, and polypropylene glycol, derivatives thereof, and combinations thereof.

11. The method of claim 10, wherein the electromigration resistive additive component has an average molecular weight in a range of about 100 to about 1000.

12. The method of claim 11, wherein the electromigration resistive additive component has an average molecular weight in a range of about 200 to about 400.

13. The method of claim 1, wherein the electroplating bath solution comprises both a suppressor additive and a wetting agent additive.

14. The method of claim 13, wherein each of the suppressor additive and the wetting agent additive comprise EO/PO random or block copolymer, derivatives thereof, and/or combinations thereof.

15. The method of claim 1, wherein the small-volume plating cell has a volume in the range of about 10 L to about 20 L.

16. The method of claim 1, wherein the plurality of substrates is a number of substrates between about 150 and about 500.

17. The method of claim 1, wherein the discarding the electroplating bath solution after the lifetime is reached comprises draining at least about 60 vol. % of the electroplating bath solution.

18. The method of claim 17, wherein the discarding the electroplating bath solution after the lifetime is reached comprises draining about 80 vol. % to about 100 vol. % of the electroplating bath solution.

19. A method for controlling electroplating bath chemistry, comprising:
(a) determining a lifetime of an electroplating bath solution having a desired chemical composition;
(b) filling a small-volume plating cell with the electroplating bath solution, the small-volume plating cell having a cathode chamber and an anode chamber, the anode chamber being separated from the cathode chamber by a membrane;
(c) plating a plurality of substrates in the electroplating bath solution until the lifetime is reached; and then
(d) discarding the electroplating bath solution after the lifetime is reached.

20. The method of claim 19, further comprising repeating (b), (c), and then (d).

21. The method of claim 19, wherein the membrane is an ionic membrane.

22. The method of claim 19, wherein the filling a small-volume plating cell with the electroplating bath solution comprises filling the cathode chamber with a catholyte solution.

23. The method of claim 22, wherein the filling a small-volume plating cell further comprises recirculating the catholyte solution to the cathode chamber.

24. The method of claim 22, wherein the catholyte solution comprises at least one anti-foaming additive component selected from the group consisting of octyl alcohol, lauryl alcohol, C6 to C20 alcohols, monohydric alcohols, polyhydric alcohols, derivatives thereof, and combinations thereof.

25. The method of claim 22, wherein the catholyte solution comprises at least one electromigration resistive additive component selected from the group consisting of isopropyl alcohol, ethylene glycol, tetraethylene glycol, polyethylene glycol, and polypropylene glycol, derivatives thereof, and combinations thereof.

26. The method of claim 19, wherein the small-volume plating cell has a volume in the range of about 1 L to about 25 L.

27. The method of claim 19, wherein the plurality of substrates is a number of substrates between about 150 and about 500.

28. The method of claim 18, wherein the discarding the electroplating bath solution after the lifetime is reached comprises draining from about 60 vol. % to about 100 vol. % of the catholyte solution.
